(19) United States
(12) Patent Application Publication
(10) Pub. No.: US 2010/0304278 A1
(43) Pub. Date: Dec. 2, 2010

(54) Method for Fabricating a Phase Shift Mask Using a Binary Blank

(75) Inventor: Youn Geun Jung, Cheongju-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/650,768

(22) Filed: Dec. 31, 2009

(30) Foreign Application Priority Data
May 26, 2009 (KR) 10-2009-0046194

(51) Int. Cl. G03F 1/00

(52) U.S. Cl. 430/5

(57) ABSTRACT

A method for fabricating a phase shift mask using a binary blank is disclosed. A light shielding pattern is formed on a transparent substrate in which a main cell region and a frame region are defined. A phase shift layer is formed that buries the light shielding pattern on the transparent substrate. A phase shift pattern is formed by removing a portion of the phase shift pattern present on the light shielding pattern. A resist layer is formed on the light shielding layer and the phase shift pattern. A resist pattern is formed that selectively exposes the light shielding pattern and the phase shift pattern in a main cell region by patterning the resist layer. The transparent substrate is exposed by etching the light shielding pattern in the main cell region using the resist pattern as an etch mask, and the resist pattern is removed.

### CROSS-REFERENCE TO RELATED APPLICATIONS

Priority to Korean patent application number 10-2009-0046194, filed on May 26, 2009, the entire disclosure of which is incorporated by reference in its entirety is claimed.

### BACKGROUND

The disclosure relates generally to a photo mask, and more particularly, to a method for fabricating a phase shift mask using a binary blank.

A photo mask functions to form a desired pattern on a wafer while light is irradiated on a mask pattern formed on a substrate and selectively transmitted light is transferred onto the wafer. As the photo mask, a binary mask has a structure in which a light transmitting region and a light shielding region for shielding light are defined on a transparent substrate. However, as the integration degree of the semiconductor device is increased and thus a pattern size is miniaturized, it becomes difficult to precisely form a desired pattern due to diffraction or interference of light transmitted through the binary mask. Accordingly, there has been developed and used a phase shift mask capable of allowing a more precise pattern than the binary mask.

The phase shift mask is fabricated by performing a patterning process on a blank mask, in which a phase shift layer, a light shielding layer and a resist layer are formed on a transparent substrate, thus forming a mask pattern to be transferred onto a wafer. The patterning process includes a first patterning process for primarily forming the mask pattern to be transferred onto the wafer as a light shielding layer, and a second patterning process for forming an intended phase shift pattern by removing a specific portion of the light shielding pattern in the circuit pattern.

A conventional phase shift mask is fabricated by performing the patterning process at least two times on a structure in which the phase shift layer and the light shielding layer are stacked. As the patterning process is performed at least two times, various problems are generated in the patterning process. For example, the portion of the light shielding pattern in which a space should be disposed between the patterns is not removed in time, and thus a bridge is generated to result in a pattern defect. The bridge generated on the mask pattern is an important defect factor that the mask is rejected in the phase shift mask fabrication process. Also, when light shielding layer residue remains on the region of the phase shift layer from which the light shielding pattern should be removed, the intended phase shift pattern is not formed. When a photo mask formed with such a phase shift pattern is used, a poor pattern is transferred onto the wafer, thereby resulting in a wafer defect. When the defect such as the bridge or residue is generated on the phase shift pattern, a repair process for removing the defect is additionally required, which increases the number of process steps and can result in an additional contamination. Also, an etch on the phase shift pattern is not sufficiently performed due to the residue, which results in deterioration of the phase shift. Further, the blank mask for the phase shift mask employs an expensive raw material usable in a light source with ArF, KrF or I-line wavelengths. As such, the total cost is increased by the blank mask employing the expensive raw material. Accordingly, there is desired a method capable of fabricating a phase shift mask more easily without defect generation.

### SUMMARY

In one aspect, a method for fabricating a phase shift mask using a binary blank includes preparing a binary blank in which a light shielding layer is formed on a transparent substrate and a resist layer is formed on the light shielding layer, forming a resist pattern that exposes a portion of a surface of the light shielding layer by patterning the resist layer, forming a light shielding pattern that exposes a portion of a surface of the transparent substrate by etching the exposed portion of the light shielding layer using the resist pattern as an etch mask, burying a portion of the transparent substrate exposed by the light shielding pattern with a phase shift layer, and forming a phase shift pattern by removing a portion of the phase shift layer present on the light shielding pattern.

In another aspect, a method for fabricating a phase shift mask using a binary blank includes forming a light shielding pattern on a transparent substrate in which a main cell region and a frame region are defined, forming a phase shift layer that buries the light shielding pattern on the transparent substrate, forming a phase shift pattern by removing a portion of the phase shift pattern present on the light shielding pattern, forming a resist layer on the light shielding layer and the phase shift pattern, forming a resist pattern that selectively exposes the light shielding pattern and the phase shift pattern in the main cell region, exposing the transparent substrate by etching the light shielding pattern in the main cell region using the resist pattern as an etch mask, and removing the resist pattern.

Forming the light shielding pattern may include preparing a binary blank in which a light shielding layer is formed on a transparent substrate and a resist layer is formed on the light shielding layer, performing a writing process for writing a shape of a pattern on the resist layer using an electron beam, forming a resist pattern including a first region shielded by the resist layer and a second region, in which some portion of the light shielding layer is exposed, by selectively removing a portion of the resist layer denatured by the writing process, and forming a light shielding pattern that exposes a portion of a surface of the transparent substrate by etching the exposed portion of the light shielding layer using the resist pattern as an etch mask.

The method may further include, after forming of the light shielding pattern, measuring a critical dimension of the space exposing a portion of a surface of the transparent substrate, and correcting a critical dimension of the light shielding pattern.

Correcting the critical dimension of the space may include performing an additional etch on the light shielding pattern when the measured critical dimension is smaller than a designed range.

Forming the phase shift pattern may be performed by a planarization process, and the planarization process may include chemical mechanical polishing.

The planarization process may be performed by recessing the phase shift layer and the light shielding pattern such that the light shielding pattern and the phase shift pattern have a height of 700 to 900 Å.

### BRIEF DESCRIPTION OF THE DRAWINGS

FIGS. 1 through 10 illustrate process steps for fabricating a phase shift mask using a binary blank.

### DETAILED DESCRIPTION

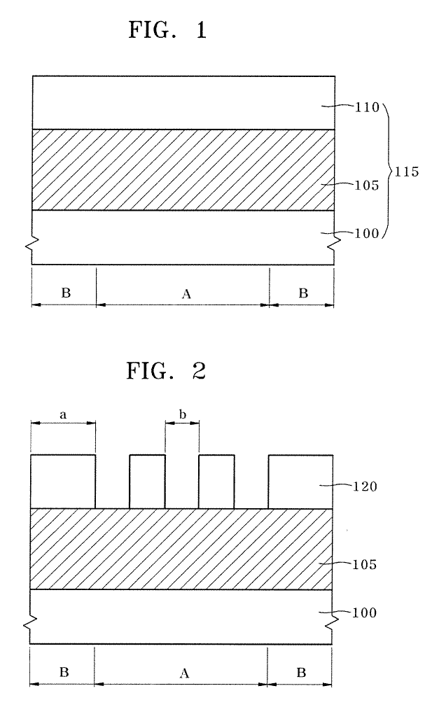

An example of a method for fabricating contacts in a semiconductor device will be described in detail with reference to the accompanying drawings. FIGS. 1 through 10 illustrate process steps for fabricating a phase shift mask using a binary blank.

Referring to FIG. 1, a binary blank mask 115 in which a main cell region A and a frame region B are defined is prepared. The binary blank 115 is made of a structure in that a light shielding layer 105 and a first resist layer 110 are stacked on a transparent substrate 100. The transparent substrate 100 contains quartz and is made of a transparent material that allows transmission of light. The light shielding layer 105 formed on the transparent substrate 100 functions to shield the light. This light shielding layer 105 can be formed as a chromium (Cr) layer.

Referring to FIG. 2, a lithography process, including a writing process and a development process, is performed on the resist layer (110, see FIG. 1) to form a resist pattern 120 that exposes some portion of a surface of the light shielding layer 105. Specifically, a first writing process for writing a shape of a pattern to be formed onto the first resist layer 110 is performed using an electron beam. Next, a development process is performed on the first resist layer 110, where the development process is subject to the first writing process. By selectively removing the denatured portion of the first resist layer 110, a first resist pattern 120 that selectively exposes some portion of the surface of the light shielding layer 105 is formed. Herein, a first region shielded by the first resist pattern 120, as denoted by the letter “a”, is a portion to be formed with a light shielding pattern, and a second region exposed by the first resist pattern 120, as denoted by the letter “b”, is a portion in which a space to be formed with a phase shift pattern is disposed.

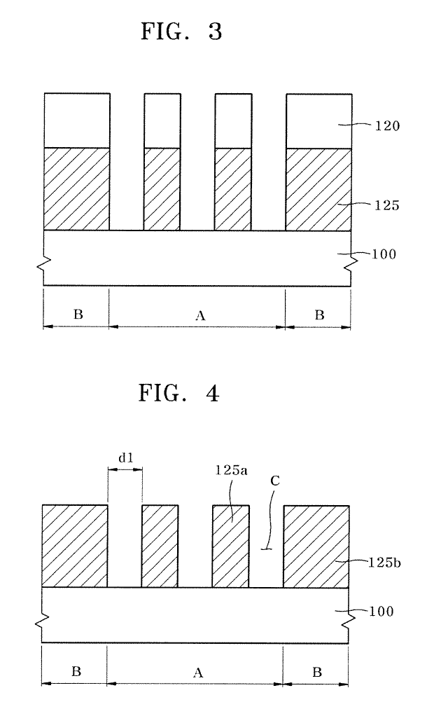

Referring to FIG. 3, the exposed portion of the light shielding layer (105, see FIG. 2) is etched using the first resist pattern 120 as an etch mask to form a light shielding pattern 125 that exposes the transparent substrate 100.

Referring to FIG. 4, the first resist pattern 120 is removed by a strip process. Then, a light shielding main pattern 125a is formed in the main cell region A, and a light shielding frame pattern 125b is formed in the frame region B. Also, a space, as denoted by the letter “C”, is disposed between the light shielding main pattern 125a and the light shielding frame pattern 125b. Next, a critical dimension (CD), denoted as “d1”, of the space C is measured. The space C disposed between the light shielding main pattern 125a and the light shielding frame pattern 125b is a region in which the phase shift pattern to be transferred onto the wafer is to be disposed. Accordingly, it is possible to estimate a critical dimension of the phase shift pattern to be finally formed by measuring the critical dimension d1 of the space C. When the measured critical dimension d1 of the space C is smaller than a designed range of the critical dimension of the space C, it is possible to correct the critical dimension of the phase shift pattern to be finally formed by using a critical dimension correction process. For example, an additional etch process is performed on the light shielding main pattern 125a or the light shielding frame pattern 125b so that the critical dimension d1 is within the designed range.

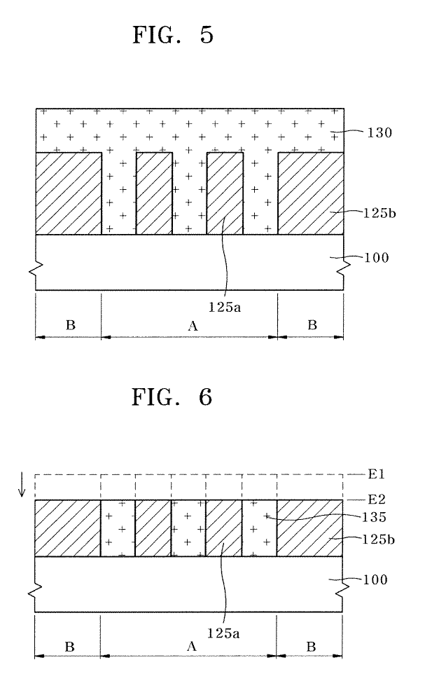

Referring to FIG. 5, a phase shift layer 130 is formed on the transparent substrate 100. Herein, the phase shift layer 130 buries the light shielding main pattern 125a, the light shielding frame pattern 125b and an exposed portion of the transparent substrate 100. The phase shift layer 130 may be formed to such a thickness that the entire space C disposed between the light shielding main pattern 125a, the light shielding frame pattern 125b can be buried. In this case, the phase shift pattern 130 is formed of a material having a transmittance of several % and can be formed of a molybdenum (Mo) based compound. Herein, the molybdenum (Mo) based compound can include molybdenum silicon (MoSi).

Referring to FIG. 6, a planarization process is performed on the phase shift layer (130, see FIG. 5) to form a phase shift pattern 135. The planarization process can be implemented by chemical mechanical polishing (CMP). Herein, the planarization process is performed by recessing a surface of the phase shift layer, as indicated by arrow in the figure, from a point E1, where surfaces of the light shielding main pattern 125a and the light shielding frame pattern 125b are exposed after removing the phase shift layer 130 material above it, to a second point E2, such that the light shielding main pattern 125a, the light shielding frame pattern 125b and the phase shift pattern 135 have a height of 700 to 900 Å. Then, the light shielding pattern 135 that buries the space (C, see FIG. 4) is formed.

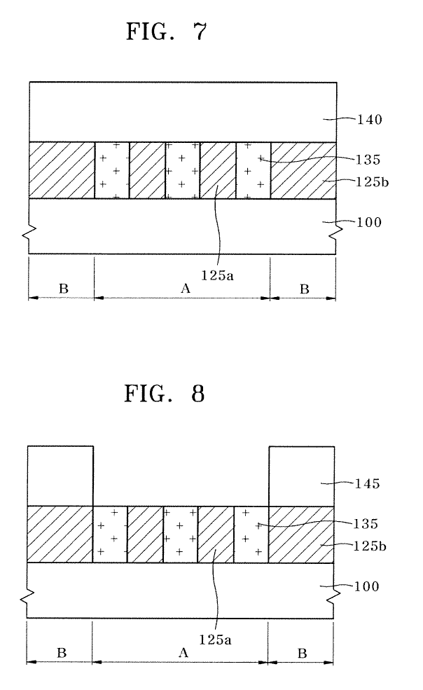

Referring to FIG. 7, a second resist layer 140 is coated on the light shielding main pattern 125a, the light shielding frame pattern 125b and the phase shift pattern 135 that are planarized. The second resist layer 140 functions as an etch mask for etching the light shielding main pattern 125a.

Referring to FIG. 8, a second lithography process, including a writing process and a development process, is performed on the second resist layer (140, see FIG. 7) to form a second resist pattern 145 that selectively exposes the main cell region A. Specifically, a second writing process is performed on the second resist layer 140 using an electron beam. Next, a development process is performed on the second resist layer 140, where the development process is subject to the second writing process. By selectively removing the denatured portion of the second resist layer 140, a second resist pattern 145 that selectively exposes the light shielding main pattern 125a and the phase shift pattern 135 in the main cell region A is formed.

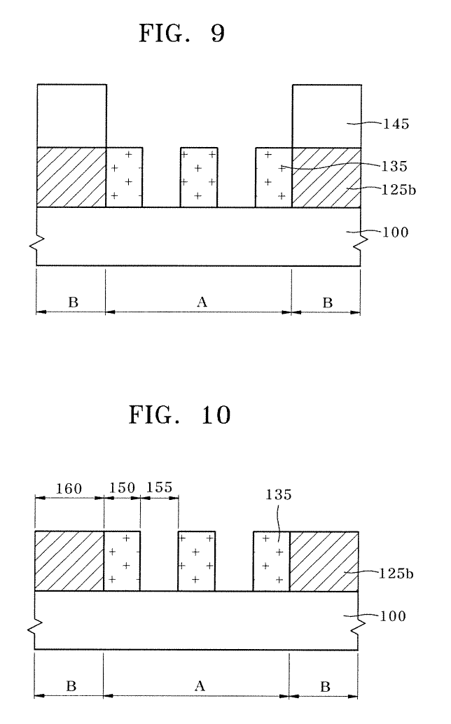

Referring to FIG. 9, the light shielding main pattern 125a exposed in the main cell region A is removed using the second resist pattern 145 as an etch mask. The light shielding main pattern 125a can be removed using an etch source capable of selectively etching chromium. Then, a phase shift region defined by the phase shift pattern 135 is disposed in the main cell region A. Herein, since the phase shift pattern 135 is formed by burying the space disposed between the light shielding main pattern 125a and the light shielding frame pattern 125b with a phase shift material, it is possible to prevent light shielding layer residue from remaining on the phase shift pattern 135.

Referring to FIG. 10, the second resist pattern 145 is removed by a strip process. Then, a phase shift region 150 defined by the phase shift pattern 135 and a light transmitting region 155 defined by exposure of the transparent substrate 100 are disposed in the main cell region A. Also, a light shielding region 160 defined by the light shielding frame pattern 125b is disposed in the frame region B.

In accordance with the above disclosure, by forming a phase shift mask using a binary blank in which a light shielding layer is formed on a transparent substrate, it is possible to prevent a bridge defect due to a light shielding pattern and also possible to prevent light shielding layer residue from remaining on the phase shift pattern. Accordingly, it is possible to omit a repair process that would otherwise be additionally performed to remove the defect, thereby reducing the process steps. Also, by forming the phase shift mask using a binary blank mask, it is possible to reduce costs.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a phase shift mask using a binary blank, comprising:
preparing a binary blank in which a light shielding layer is formed on a transparent substrate and a resist layer is formed on the light shielding layer;
forming a resist pattern that exposes a portion of a surface of the light shielding layer by patterning the resist layer;
forming a light shielding pattern that exposes a portion of a surface of the transparent substrate by etching the exposed portion of the light shielding layer using the resist pattern as an etch mask;
burying a portion of the transparent substrate exposed by the light shielding pattern with a phase shift layer; and
forming a phase shift pattern by removing a portion of the phase shift layer present on the light shielding pattern.

2. The method of claim 1, further comprising, after forming the light shielding pattern:
measuring a critical dimension of a space exposing a portion of a surface of the transparent substrate; and
correcting a critical dimension of the light shielding pattern.

3. The method of claim 2, wherein correcting the critical dimension of the space comprises: performing an additional etch on the light shielding pattern when the measured critical dimension is smaller than a designed range.

4. The method of claim 1, wherein forming the phase shift pattern is performed by a planarization process.

5. A method for fabricating a phase shift mask using a binary blank, comprising:
forming a light shielding pattern on a transparent substrate in which a main cell region and a frame region are defined;
forming a phase shift layer that buries the light shielding pattern on the transparent substrate;
forming a phase shift pattern by removing a portion of the phase shift pattern present on the light shielding pattern;
forming a resist layer on the light shielding layer and the phase shift pattern;
forming a resist pattern that selectively exposes the light shielding pattern and the phase shift pattern in the main cell region;
exposing the transparent substrate by etching the light shielding pattern in the main cell region using the resist pattern as an etch mask; and
removing the resist pattern.

6. The method of claim 5, wherein forming the light shielding pattern comprises:
preparing a binary blank in which a light shielding layer is formed on a transparent substrate and a resist layer is formed on the light shielding layer;
performing a writing process for writing a shape of a pattern on the resist layer using an electron beam;
forming a resist pattern including a first region shielded by the resist layer and a second region, in which some portion of the light shielding layer is exposed, by selectively removing a portion of the resist layer denatured by the writing process; and
forming a light shielding pattern that exposes a portion of a surface of the transparent substrate by etching the exposed portion of the light shielding layer using the resist pattern as an etch mask.

7. The method of claim 6, further comprising, after forming of the light shielding pattern:
measuring a critical dimension of the space exposing a portion of a surface of the transparent substrate; and
correcting a critical dimension of the light shielding pattern.

8. The method of claim 7, wherein correcting the critical dimension of the space comprises: performing an additional etch on the light shielding pattern when the measured critical dimension is smaller than a designed range.

9. The method of claim 5, wherein forming the phase shift pattern is performed by a planarization process.

10. The method of claim 9, wherein the planarization process includes chemical mechanical polishing.

11. The method of claim 9, wherein the planarization process is performed by recessing the phase shift layer and the light shielding pattern such that the light shielding pattern and the phase shift pattern have a height of 700 to 900 Å.
